(19) United States
(12) Patent Application Publication
(10) Pub. No.: US 2016/0037633 A1
(43) Pub. Date: Feb. 4, 2016

(54) FLEXIBLE ELECTRONIC FIBER-REINFORCED COMPOSITE MATERIALS

(71) Applicant: DSM IP ASSETS B.V., Heerlen (NL)

(72) Inventors: Roland Joseph Downs, Mesa, AZ (US); Christopher Michael Adams, Mesa, AZ (US)

(21) Appl. No.: 14/774,594

(22) PCT Filed: Mar. 13, 2014
(86) PCT No.: PCT/US2014/026856

§ 371 Date: Sep. 10, 2015

Related U.S. Application Data
(60) Provisional application No. 61/780,829, filed on Mar. 13, 2013.
(60) Provisional application No. 61/784,968, filed on Mar. 14, 2013.

(51) Int. Cl. H05K 1/03; H05K 3/46; H05K 1/02; H05K 3/02

(52) U.S. Cl. CPC H05K 1/0366; H05K 3/02; H05K 3/46; H05K 1/028; H05K 1/0271; H05K 2201/068

(57) ABSTRACT

The present disclosure describes multilayer fiber-reinforced electronic composite materials comprising at least one conductive layer and at least one laminate layer further comprising at least one reinforcing layer. In various embodiments, the conductive layer is a continuous metal layer, an etched-metal layer, a metal ground plane, a metal power plane, or an electronic circuitry layer. In various embodiments, the laminate layer comprises an arrangement of unidirectional tape sub-layers to provide fiber-reinforcement and various film layers. The composite materials herein find use as flexible circuit boards, ruggedized flexible electronic displays, and other assemblies requiring flexibility and strength.

### CROSS-REFERENCE TO RELATED APPLICATIONS

This application claims priority to U.S. Provisional Patent Application Ser. No. 61/780,829 filed Mar. 13, 2013, and U.S. Provisional Patent Application Ser. No. 61/784,968 filed Mar. 14, 2013, which are incorporated herein by reference in their entirety.

### FIELD OF THE INVENTION

The present disclosure relates generally to multilayer electronic composites and in particular to flexible electronic fiber-reinforced composites and methods of manufacturing same.

### BACKGROUND OF THE INVENTION

Electronics depend upon precise location and dimensional tolerance of elements and features such as circuits and traces, even to the micron level, and are trending to an even smaller scale. Current flexible electronic technology is based on low strength, low modulus, unreinforced plastic film with a high Coefficient of Thermal Expansion (CTE), low thermal conductivity and high moisture uptake with attendant problems lack of dimensional stability due to moisture swelling and degradation of dielectric properties. Such plastic films must be relatively thick to carry out proper function, and have sufficient mechanical properties to provide a substrate with low stretch, for dimensional stability and sufficient strength and tear resistance to provide sufficient durability. The high Coefficient of Thermal Expansion (CTE) provides poor dimensional stability under relatively small variations in temperature and the low thermal conductivity causes high temperatures due to dissipate the heat generated by power consuming circuit elements. The lack of thermal stability combined with, low moisture swelling properties, thus providing a substrate with insufficient dimensional stability to withstand fabrication processes, thermal strains and providing in-service durability and in stability of electronic elements that require dimensional stability for optimum performance

The end result is that resolution, durability and stability of printed electronic components on flexible substrates is currently limited by the properties of the substrate. Ideally, thin flexible substrates should have sufficiently high heat transfer coefficient to control the planar directionality of heat flow. Thermal expansion and non-thermal mechanical deformation of the substrates can create instability and damage to electronic circuits. Moisture resistance may be critical to shield the electronic circuits from damage and to provide consistent and optimal dielectric properties, and having a smooth surface receptive to printing and/or depositing of electronically conductive material is desirable in the creation of electronic structures.

The inadequacy and instability of currently-available thin film substrates creates limitations in the accuracy and size of electronic structures created from them. As such, there is a need for thin, flexible, dimensionally stable substrates usable for flexible electronic composites. Due to the orientability, in particular composites composed of oriented layers of unidirectional engineering fibers, of layered composite construction such composites may have their mechanical and thermal expansion properties engineered to match or complement the properties of the electronic elements incorporated inside them or on their surfaces. Furthermore, the thermal conduction properties can similarly be optimized for application specific uniformity or directionality of heat transfer. The thinness of the composite substrate reduces strains due bending and flexing of the flexible electronic elements, especially on the inner and outer surfaces. Additionally the multilayer configuration of the composites allows strain sensitive electronic elements to be positioned close to the neutral axis of bending to minimize deformations due to bending or flexing.

### SUMMARY OF THE INVENTION

In various embodiments of the present disclosure, flexible electronic composite systems comprise a flexible electronic composite material comprising at least one conductive layer and at least one fiber-reinforced laminate layer. Conductive layers include non-etched copper films, etched copper films, copper ground plane, copper power plane, electronic circuitry, and the like. Fiber-reinforced laminate layers comprise, for example, laminates of unidirectional fiber-reinforced tapes with various film layers. In various embodiments, fiber-reinforced laminate layers are non-conductive layers. In other embodiments, fiber-reinforced laminate layers are conductive, such as by the presence of metallic constituents or other conductive materials e.g. carbon nanoparticles in the resin, and/or in the fibers, within fiber-reinforced layers.

In various embodiments, flexible electronic composite systems in accordance with the present disclosure may further comprise additional electronic hardware and/or software, such as for example, computer chips with written code, batteries, LED displays, broadcast coils, pressure-sensitive switches, and the like. Such systems may comprise final marketable electronic products or may be further incorporated as electronic elements within products requiring electronics, such as for example, pallets having RFID tracking, or clothing having entertainment, safety or tracking electronics. In various embodiments, flexible electronic composite systems comprise a flexible electronic composite material incorporated within or on a consumer, industrial, institutional or government product requiring an electronic aspect.

In various embodiments, unidirectional fiber-reinforced layers form thin and smooth substrates suitable for etching or printing of electronic circuitry thereon. In various embodiments, composite materials in accordance with the present disclosure provide smooth surfaces suitable for etching or printing of electronic circuitry thereon.

In various embodiments, electronic composite systems of the present disclosure overcome many of the prior deficiencies of electronic substrates, such as, low thermal conductivity, high substrate weight, low substrate durability, instability and non uniformity of thermal and non-thermal expansion and shrinkage, and mismatch between the thermal expansion properties of the substrate and electronic elements, lack of moisture resistance and resulting instability of dielectric stability, and lack of sufficient smoothness for printing and deposition of electronic elements and conductive materials.

In various embodiments, multi-layered flexible electronic composites of the present disclosure can be manufactured by repetitive addition of conductive and/or non-conductive layers, as desired, to produce multi-layered composites. In various embodiments, a method of manufacturing a flexible electronic composite material comprises: adding a reinforcing layer onto a conductive layer; optionally curing the composite; optionally etching the conductive layer; and optionally adding further conductive and/or non-conductive layers thereon.

### BRIEF DESCRIPTION OF THE DRAWINGS

The accompanying drawings are included to provide a further understanding of the disclosure and are incorporated in and constitute a part of this specification, illustrate embodiments of the disclosure, and together with the description serve to explain the principles of the disclosure, wherein:

FIG. 1 illustrates a perspective view of an embodiment of a composite material in accordance with the present disclosure;

FIG. 2 illustrates a perspective view of an embodiment of a composite material in accordance with the present disclosure;

FIG. 3 illustrates a perspective view of an embodiment of a composite material in accordance with the present disclosure;

FIG. 4 illustrates a perspective view of an embodiment of a composite material in accordance with the present disclosure;

FIG. 5 illustrates a perspective view of an embodiment of a composite material in accordance with the present disclosure; and

FIG. 6 illustrates a front plan view of an embodiment of a circuitry layer usable within various composite materials in accordance with the present disclosure.

### DETAILED DESCRIPTION OF THE INVENTION

The following description is of various exemplary embodiments only, and is not intended to limit the scope, applicability or configuration of the present disclosure in any way. Rather, the following description is intended to provide a convenient illustration for implementing various embodiments including the best mode. As will become apparent, various changes may be made in the function and arrangement of the elements described in these embodiments without departing from principles of the present disclosure.

As described in more detail herein, various embodiments of the present disclosure generally comprise multi-layered flexible electronic composites comprising at least one conductive layer and at least one fiber-reinforced laminate layer. In various embodiments, the at least one fiber-reinforced laminate layer comprises directionally aligned monofilaments. In various embodiments, at least one fiber-reinforced laminate layer comprises any number of unidirectional tapes, such tapes having any relative orientation of fiber direction between them.

TABLE 1 provides a glossary of terms and definitions that may be used in various portions of the present disclosure.

TABLE 1
BRIEF GLOSSARY OF TERMS AND DEFINITIONS

| | |
|---|---|
| Adhesive | A resin used to combine composite materials. |
| Anisotropic | Not isotropic; having mechanical and or physical properties which |
| | vary with direction at a point in the material. |
| Areal Weight | The weight of fiber per unit area, often expressed as grams per square |
| | meter (g/m²). |
| Autoclave | A closed vessel for producing a pressurized environment, with or |
| | without heat, to an enclosed object which is undergoing a chemical |
| | reaction or other operation. |
| B-stage | Generally defined herein as an intermediate stage in the reaction of |
| | some resin systems. Materials are sometimes pre-cured to this stage, |
| | called “prepregs”, to facilitate handling and processing prior to final |
| | cure. |
| C-Stage | Final stage in the reaction of certain resins in which the material is |
| | relatively insoluble and infusible. |
| Cure | To change the properties of a polymer resin irreversibly by chemical |
| | reaction. Cure may be accomplished by addition of curing (cross- |
| | linking) agents, with or without catalyst, and with or without heat. |
| Decitex (DTEX) | Unit of the linear density of a continuous filament or yarn, equal to |
| | 1/10th of a tex or 9/10th of a denier. |
| Filament | The smallest unit of a fiber-containing material. Filaments usually are |
| | of long length and small diameter. |
| Polymer | An organic material composed of molecules of monomers linked |
| | together. |
| Prepreg | A ready-to-cure sheet or tape material. The resin is partially cured to |
| | a B-stage and supplied to a layup step prior to full cure. |
| Tow | A bundle of continuous filaments. |
| UHMWPE | Ultra-high-molecular-weight polyethylene. A type of polyolefin made |
| | up of extremely long chains of polyethylene. Trade names include |
| | Spectra ® and Dyneema ®. |
| Unitape | Unidirectional tape (or UD tape) - flexible reinforced tapes (also |
| | referred to as sheets) having uniformly-dense arrangements of |
| | reinforcing fibers in parallel alignment and impregnated with an |
| | adhesive resin. UD tapes are typically B-staged and can be used as |
| | layers for the composites herein. |
| PCB | Printed Circuit Board |

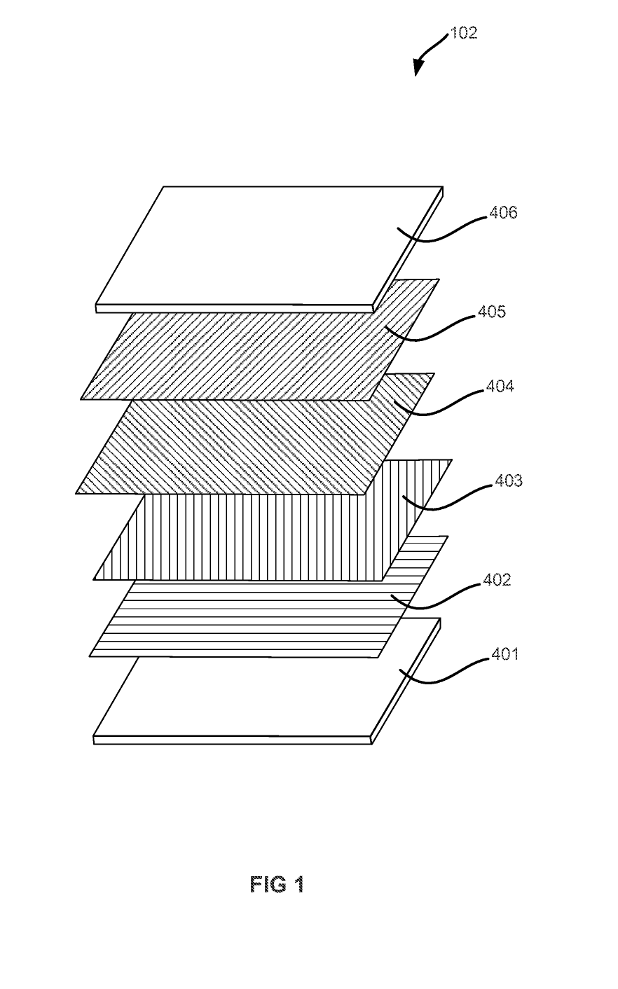

The above being noted, with reference now to FIG. 1, an embodiment of a composite material in accordance with the present disclosure is illustrated. FIG. 1 shows, in perspective view, a diagrammatic illustration of a flexible electronic fiber-reinforced composite material 102 according to various embodiments of the present disclosure. In various embodiments, composite material 102 may be conductive or non-conductive. Composite material 102 can be constructed from multiple layers. In various embodiments, composite material 102 comprises, for example two, three, four, five, six, seven, eight, or more, or many more layers. For example, composite material 102 can comprise at least one front surface layer 401, at least one back surface layer 406 and at least one reinforcing layer, such as reinforcing layer 402, reinforcing layer 403, reinforcing layer 404, and reinforcing layer 405, as shown. In various embodiments, either or both front surface layer 401 and/or back surface layer 406 is/are printable with conductive materials, or otherwise amenable to deposition of conductive materials.

Film layers, such as front surface layer 401 and back surface layer 406, are coatings or films made from materials typical of electronic materials, such as, polyimide, PEN, Mylar, glass, amorphous silicone, graphene, organic or inorganic semiconductors, or others. Alternate preferred films include metalized films or thin metal layers. Other alternate preferred embodiments include interlayers of such films. Other alternate preferred embodiments omit such films.

Reinforcing layers, such as reinforcing layers 402, 403, 404 and 405 illustrated in FIG. 1, may comprise one or any number of unidirectional tape (“unitape”) sub-layers. A unidirectional tape is a fiber-reinforced layer having thinly spread parallel monofilaments coated by a resin. In various embodiments, resin may be a curable resin or any type of non-curing resin. In various embodiments, each unitape sub-layer having parallel fibers is inherently directionally oriented, in a dedicated direction, to limit stretch and provide strength in such chosen direction. In various embodiments, a two-direction unitape construction may feature the first unitape sub-layer disposed at substantially (+/−several degrees) a 0° orientation and the second unitape sub-layer disposed at substantially a 90° orientation. In the same manner, various one-direction configurations, two-direction combinations, three-direction combinations, four-direction combinations, and other unitape combinations, may be applied to create laminates having a desired directional or non-directional reinforcement. For example, in various embodiments, four layers of unidirectional tape sub-layers may be laminated in a substantially 0°/+45°/+90°/+135° relative orientation of their fibers to create an overall cross-hatched and multi-directional reinforcement.

In various embodiments, fiber types suitable for reinforcing unitape sub-layers include UHMWPE (trade names Spectra, Dyneema), Vectran, Aramid, polyester, nylon, and other fibers. Depending on temperature requirements of secondary processing procedures, and other considerations, it may be necessary to choose a high melt temperature fiber such as Vectran rather than UHMWPE, which melts above 290° F. UHMWPE has advantages for flexible electronics including high strength, high thermal conductively, and excellent flex fatigue resistance.

Compared to traditional woven fabrics of the same weight, unitape reinforcing layers are significantly thinner, flatter, stronger, and more tear resistant. Oftentimes, when a more durable circuit material is desired, a thicker substrate film is chosen. Rather, for similar or even improved properties, a substrate that includes the thin fiber-reinforced unitape layers in accordance with the present disclosure can be utilized.

In various embodiments, reinforcing layers within composite materials of the present disclosure comprise at least one unidirectional tape having monofilaments therein, all of such monofilaments lying in a predetermined direction within the tape, wherein such monofilaments have diameters less than about 60 microns and wherein spacing between individual monofilaments within an adjoining strengthening group of monofilaments is within a gap distance in the range between abutting and/or stacked monofilaments up to about 300 times the monofilament major diameter. In various embodiments, abutted and/or stacked monofilaments form a reinforcing layer that is one or multiple monofilament layers thick, depending on strength and modulus considerations of the composite material design. In various embodiments, abutting and/or stacked monofilaments produce a substantially flat reinforcing layer that is beneficial but not required for this invention.

In various embodiments, the monofilaments within reinforcing layers, such as reinforcing layers 402, 403, 404 and 405, illustrated in FIG. 1, are extruded. In various embodiments, reinforcing layers include at least two unidirectional tapes, each having extruded monofilaments therein, all of such monofilaments lying in a predetermined direction within the tape, wherein such monofilaments have diameters less than about 60 microns and wherein spacing between individual monofilaments within an adjoining strengthening group of monofilaments is within a gap distance in the range between abutting and/or stacked monofilaments up to about 300 times the monofilament major diameter. In various embodiments, abutted and/or stacked monofilaments form a reinforcing layer that is one or multiple monofilament layers thick (stacked), depending on strength and modulus considerations of the composite material design.

In various embodiments, such at least two unidirectional tapes include larger areas without monofilaments therein, and wherein such larger areas comprise laminar overlays comprising smaller areas without monofilaments. Such smaller areas can comprise user-planned arrangements, such as to provide different flexibility between various regions of a laminate composite material. In various embodiments, a composite material may comprise reinforcing laminate layers wherein a first one of at least two unidirectional tapes includes monofilaments lying in a different predetermined direction than a second one of at least two unidirectional tapes.

In various embodiments, a reinforcing layer, such as reinforcing layers 402, 403, 404 and 405, illustrated in FIG. 1, comprises a laminate of unidirectional tapes wherein a combination of the different predetermined directions of such at least two unidirectional tapes is user-selected to achieve laminate properties having planned directional rigidity/flexibility. In various embodiments, a composite material comprises multiple laminate segments attached along peripheral joints, such as for example to provide a bendable joint in PCB's for electronics. For example, a composite material may comprise at least one laminate segment attached along peripheral joints with at least one non-laminate segment. In various embodiments, a composite material comprises multiple laminate segments attached along area joints.

In various embodiments, a composite material comprises at least one laminate segment attached along area joints with at least one unidirectional tape segment. Additionally, in various embodiments, a composite material comprises at least one laminate segment attached along area joints with at least one monofilament segment. Also, in various embodiments, a composite material further comprises at least one rigid element.

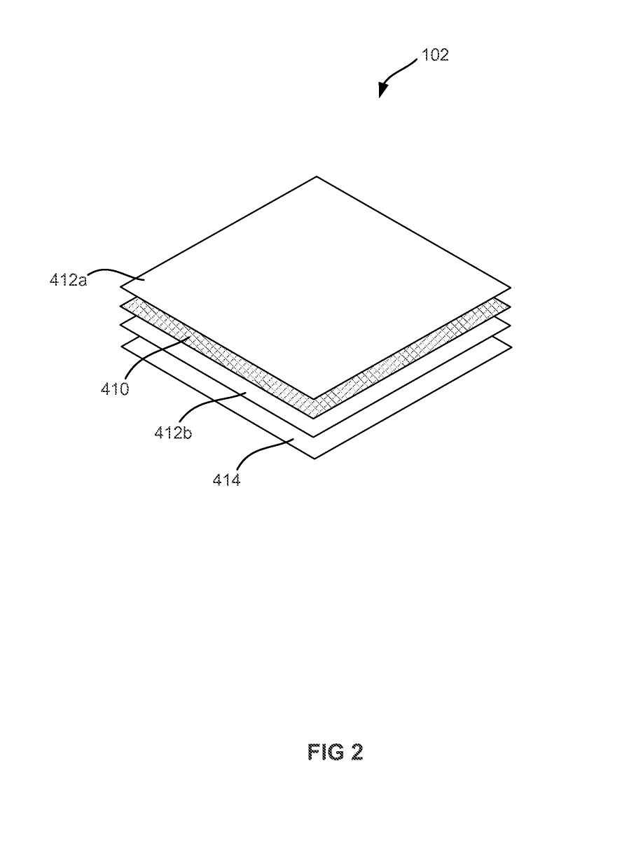

With reference now to FIG. 2, an embodiment of composite material 102 is diagrammatically illustrated in perspective view. Composite material 102 comprises at least one conducting layer, such as for example, continuous copper layer 414 that may be etched at a later time by a manufacturer, sub-manufacturer or end user, or left as is within the composite material 102. In various embodiments, such a conductive layer may comprise any metalized material, such as copper, that may be masked and etched to form electrical circuits. Circuit elements of one or more layers may also be printed using conductive silver or silver , gold, copper , zinc, carbon based or semiconductor or organic electrically active inks or polymers using printing methods such as gravure, flexo, anilox, screen printing, ink jet printing techniques. These inks may be cured using UV, room temperature catalyst curing or thermal curing .Typical conductive printable materials are Dupont Solamet PV 412 silver based for photovoltaic applications for current collection in applications requiring fine line resolution, high conductivity and low contact resistance, Dupont 5064 silver in screen printing of antennas and general printed electronics requiring high electrical conductivity, Dupont 5874 silver based materials and 7105 carbon based materials for screen printing of highly stable electrode systems, Dupont 5069 silver and 5067 carbon flexographic and Dupont 5064 silver screen printing formulations for printing of conductive tracks . Flexible heating elements can be printed using Dupont 7282 Positive Temperature Coefficient (PTC) carbon resistor/silver for self-regulating heater applications. Printed flexible batteries can also be fabricated using various combinations of silver, carbon and zinc based inks. For luminescent and light emoting applications DuPont Luxprint electroluminescent polymer for screen printing may be used. For applications requiring more durable or stable electronic traces or elements Novacentrics Metalon-JS series silver based inkjet inks, Metalon-ICI series copper oxide reduction inks for screen, inkjet flexo and gravure printing and Metalon HPS series silver based inks for screen print applications can be printed and the resulting printed elements can be dried, sintered and annealed using Novacentrix PulseForge photonic post processing.

In this illustrated embodiment, composite material 102 may be constructed by using one conductive layer portion or multiple conductive layer portions.

In various embodiments for example, the conductive layer, such as copper layer 414, may be disposed in continuous or discontinuous segments or portions, in planar arrangement, pressed or adhered against a common adjacent co-planar layer. As shown in FIG. 2, composite material 102 comprises a first film layer 412a, laminated layer 410, a second film layer 412b, and copper layer 414. In this particular embodiment, laminated layer 410 is sandwiched between film layers 412a and 412b, although in various other embodiments, different arrangements of layers may be desirable. In various embodiments, such as FIG. 2, laminate layer 410 comprises a multilayered structure, (such as shown in FIG. 1), comprising a front surface layer 401, reinforcing layer 402, reinforcing layer 403, reinforcing layer 404, reinforcing layer 405, and a back surface layer 406, wherein each reinforcing layer may comprise any number and orientation of unidirectional tapes, each unidirectional tape comprising monofilaments.

In various embodiments, composite material 102 can be used as a substrate on which electrical circuits are printed. The mechanical and thermal dimensional stability of various embodiments of the composite material 102 herein allows for ease in processing. The fiber type and content as well as choice of surface films create low thermal expansion materials or materials with matched thermal expansion for a particular process or application.

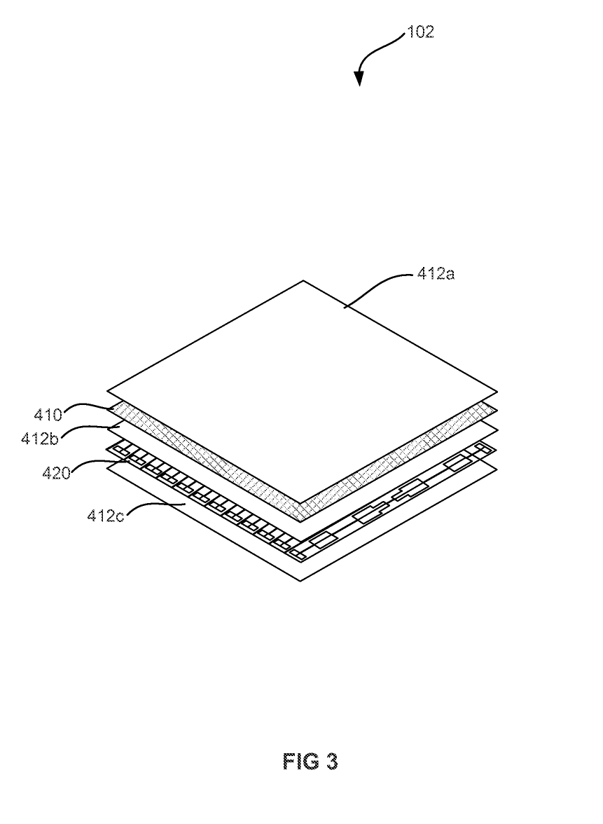

Referring now to FIG. 3, an embodiment of composite material 102 is diagrammatically illustrated in perspective view. Composite material 102 comprises a conductive circuit layer in the form of an etched copper layer 420. The etched-copper layer 420 may comprise an etching that traces an electronic circuit design. In various embodiments, composite material 102 is constructed from multiple layered portions, whereby circuits are pre-processed on film substrates and the user adds unidirectional tape reinforcing layers as desired. In the embodiment illustrated in FIG. 3, composite material 102 comprises film layer 412a, laminate layer 410, film layer 412b, etched-copper layer 420, and film layer 412c. In various other embodiments, different arrangements of conductive and non-conductive layers may be desirable. In various embodiments, film layer 412a and/or film layer 412c may be amendable to the printing or deposition of metallic materials thereon. In various embodiments, such as FIG. 3, laminate layer 410 comprises a multilayered structure, (such as shown in FIG. 1), comprising a front surface layer 401, reinforcing layer 402, reinforcing layer 403, reinforcing layer 404, reinforcing layer 405, and a back surface layer 406, wherein each reinforcing layer may comprise any number and orientation of unidirectional tapes, each unidirectional tape comprising monofilaments.

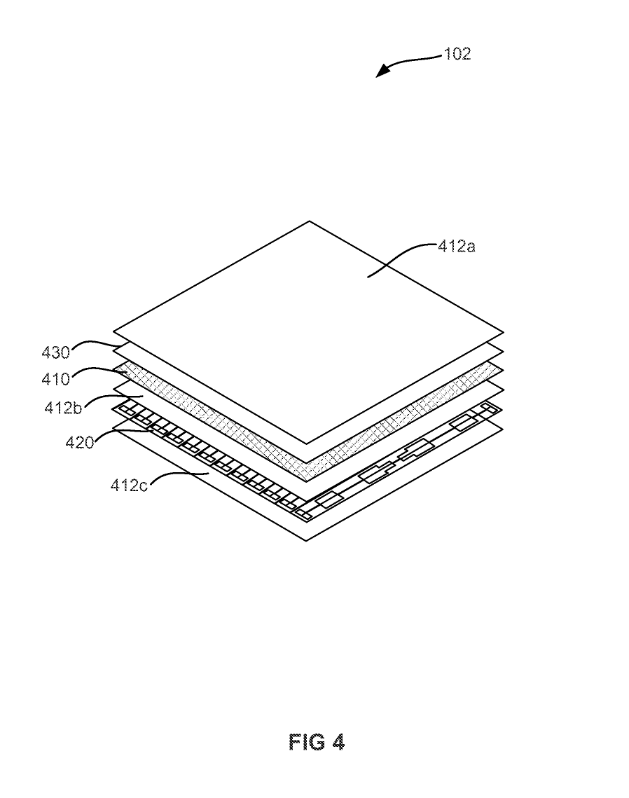

With reference now to FIG. 4, an embodiment of composite material 102 is diagrammatically illustrated in perspective view. Composite material 102 comprises an additional conductive layer, namely, copper ground plane layer 430. In the embodiment illustrated, composite material 102 comprises film layer 412a, copper ground plane layer 430, laminate layer 410, film layer 412b, etched-copper layer 420, and film layer 412c. In various embodiments, a conductive layer is any one of a non-etched metal layer, an etched-metal layer, a metal ground plane layer, a metal power plane layer, or an electronic circuitry layer. In various embodiments, such as FIG. 4, laminate layer 410 comprises a multilayered structure, (such as shown in FIG. 1), comprising a front surface layer 401, reinforcing layer 402, reinforcing layer 403, reinforcing layer 404, reinforcing layer 405, and a back surface layer 406, wherein each reinforcing layer may comprise any number and orientation of unidirectional tapes, and wherein each unidirectional tape comprises monofilaments.

In various embodiments, copper ground plane layer 430 may be disposed directly adjacent and co-planar to the etched-copper layer 420, or separated, as needed, by any number of intervening film layers or other non-conductive or conductive layers. In various embodiments, a conductive layer, such as copper ground plane layer 420, may operate as a power plane rather than a ground plane. In various embodiments, composite material 102 can comprise any number of etched-copper layers 420 and any number of copper ground plane or power plane layers 430, intermixed with any number of film layers, laminate layers, or any other conductive and/or non-conductive layers, in any arrangement, to produce multilayer PCB's.

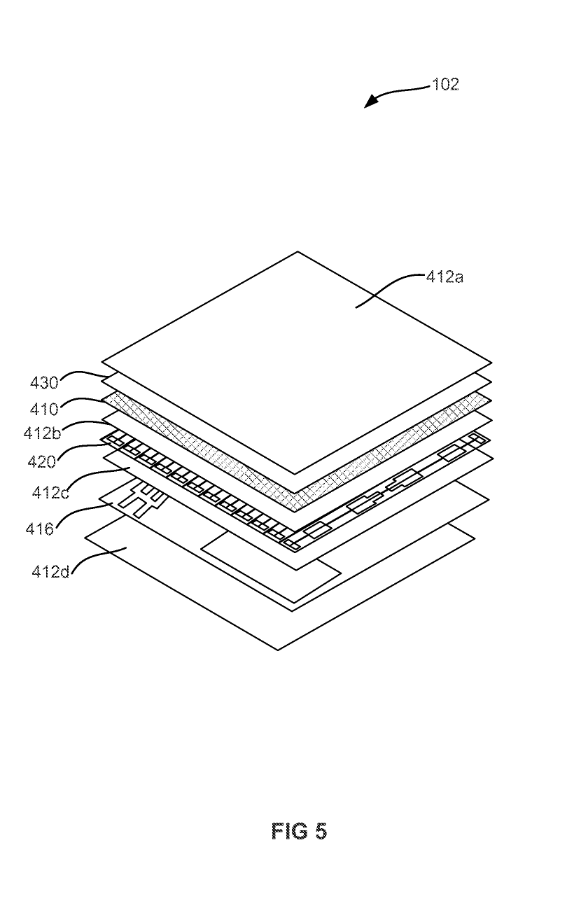

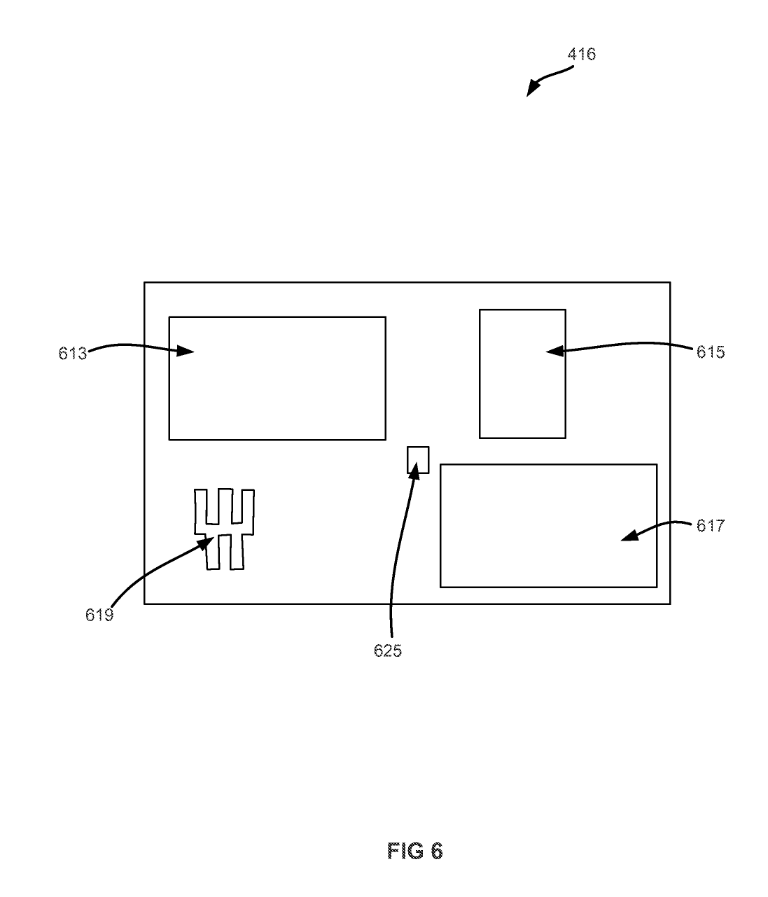

With reference now to FIG. 5, an embodiment of composite material 102 is diagrammatically illustrated in perspective view. In the manufacturing of composite material 102, circuits may be added to multiple layers of the composite materials that return for one or more lamination steps to produce multilayered flexible composite PCBs. Composite material 102 comprises film layer 412a, copper ground plane or copper power plane layer 430, laminate layer 410, film layer 412b, etched-copper layer 420, film layer 412c, circuitry layer 416, (discussed in more detail below in reference to FIG. 6), and film layer 412d. In various embodiments, such as FIG. 5, laminate layer 410 comprises a multilayered structure, (such as shown in FIG. 1), comprising a front surface layer 401, reinforcing layer 402, reinforcing layer 403, reinforcing layer 404, reinforcing layer 405, and a back surface layer 406, wherein each reinforcing layer may comprise any number and orientation of unidirectional tapes, and wherein each unidirectional tape comprises monofilaments. In various embodiments, composite material 102 can comprise any number of etched-copper layers 420, any number of circuitry layers 416, and any number of copper ground plane or power plane layers 430, intermixed with any number of film layers, laminate layers, or any other conductive and/or non-conductive layers, in any arrangement, to produce multilayer PCB's. For example, in various embodiments, circuitry layer 416 may appear as the very top layer in a composite material 102. In various other embodiments, circuitry layer 416 may appear as the layer second to the top within a composite material 102, covered for example by a single protective film layer so that various display, antenna, and photovoltaic elements can still operate, and/or remain visible through, the protective film.

Referring now to FIG. 6, a front plan view of an embodiment of an electronic circuitry layer 416 is illustrated. Such a circuitry layer, or any conceivable embodiment of a circuitry layer, can be used within the composite materials of the present disclosure. As used herein, a circuitry layer means an assemblage of electronic components as is meant to be distinct from a bare etched circuit design (see element 420 above). In this particular embodiment, circuitry layer 416 comprises display 613, antenna 615, photovoltaic element 617, printed circuitry 619 and discrete sensor 625, although in other embodiments, any other componentry and arrangements are within the scope of the present disclosure.

Composite materials according to the present disclosure typically weigh between about 10 g/m² and about 150 g/m², such as for example, between about 12 g/m² and about 133 g/m². Additionally, composite materials in accordance with the present disclosure are typically between about 35 lb/in (35,000 psi) and about 515 lb/in (73,000 psi) in tensile strength. In various embodiments, composite materials exhibit approximately 3% elongation failure and modulus between approximately 1200 lb/in (1,200,000 psi) and 17,000 lb/in (2,400,000 psi). In various embodiments, composite materials according to the present disclosure are typically about 0.001″ to about 0.007″ in thickness. In various embodiments, composite materials in accordance with the present disclosure have fiber or filament stacking ranging from side by side or stacked to a center to center distance of approximately 300-fiber diameters.

In various embodiments, a method for manufacturing a flexible composite material comprises: forming a multilayer composite by adding at least one reinforcing layer to at least one conductive layer; and optionally curing the multilayered composite by pressure, vacuum and/or heat. In various embodiments, the method further comprises the step of etching said conductive layer. In various embodiments, the method further comprises the adding of additional conductive and/or non-conductive layers to the multilayered composite, either before or after said optional curing. In various embodiments, non-conductive film layers are added to the multilayered composite, such as between any conductive and/or non-conductive layers, or as outer insulating or protective layers on one or both of the outer surfaces of the multilayered composite, before and/or after said optional curing.

In various embodiments, layers within a multilayered composite material can be combined and cured together using pressure and temperature, either by passing the stacked layers through a heated set of nips rolls, a heated press, a heated vacuum press, a heated belt press or by placing the stack of layers into a vacuum lamination tool and exposing the stack to heat. Vacuum lamination tools can be covered with a vacuum bag and sealed to the lamination tool with a vacuum applied to provide pressure. Moreover, external pressure, such as available in an autoclave, can be used in the manufacture of various embodiments of the composite materials, herein, and may be used to increase the pressure exerted on the layers. The combination of pressure and vacuum that the autoclave provides results in flat, thin, and well consolidated materials. Under appropriate circumstances, considering such issues as design preference, user preferences, marketing preferences, cost, structural requirements, available materials, technological advances, etc., any other conceivable lamination method(s) may suffice.

Composite materials in accordance with the present disclosure have at least one or more of the following advantages over traditional monolithic circuit substrates: high strength-to-weight and strength-to-thickness, rip-stop, low or matched thermal expansion, tailored dielectric properties, and engineered directional in plane and transverse, out of plane, thermal conductivities to provide tailored application specific heat transfer properties. Additionally, the fiber reinforcement type, quantity, and orientation can be used to control and tailor heat flow and directional strength because of the preference for heat and stress to travel along the oriented polymer chains in engineering fibers.

Applications for the composite materials of the present disclosure include, but are not limited to, tightly assembled electronic packages, electrical connections where flexing is required during use, and electrical connections to replace heavier wire harnesses. Such product forms include flexible displays, flexible solar cells, and flexible antennas, and the like.

System embodiments include, but are not limited to:

Single Layer embodiment: A composite material comprising at least one conducting layer such as a continuous copper layer that may be etched by the user;

Multilayer embodiments: Circuits pre-processed on film substrates whereby the manufacturer, sub-manufacturer or user adds the unitape reinforcing layers and film layers;

Layer by layer processed embodiments: Circuits are added to single layer materials that return for one or more lamination steps to produce a multilayered flexible composite.

Composite materials in accordance with the present disclosure may exhibit one or more of the following properties:

Strength;

Low stretch;

Strength properties that can be engineered to match a required design;

Low CTE that closely matches that of many materials used in electronics, emerging technologies, and nano-technologies;

Thermal expansion that can be isotropic for uniform, predictable, and strain matched thermal expansion. Such property allows for small, fine scale, circuits and electronic elements to be fabricated to precise tolerance in fine resolution and to maintain that space orientation relative to each other over wide temperature variations so circuit elements will maintain design performance tolerance in all directions and in plane; and/or

High isotropic or engineered anisotropic in-plane modulus, to provide low in-plane mechanical stretch due to mechanical loading, which allows the mechanical property analog of the CTE uniformity described above. The low stretch means that circuit elements do not change dimensions, and/or the distance between features does not change due to load. The dimensional stability provided by the high modulus and engineered directional properties improve the resolution and registration of electronic elements and devices which enable smaller circuit designs and the incorporation of smaller and tighter transistor, device or circuit elements to enable higher density electronic design and integration for flexible electronics. Since the performance and reliability of circuits depends upon the special resolution of the lateral distances between the electrodes or elements within a device, the ability to maintain those resolutions under flex, bending or thermal cycling and the overlay accuracy and registration between different circuit or device patterns or layers a low stretch, dimensionally stable substrate under mechanical loads, flex due to bending or thermal strains improves performance and device stability. For flexible displays the dimensional stability improves image resolution and clarity. The low stretch reinforcement enables the use polymer materials that have superior environmental stability and resistance to degradation, superior dielectric property stability, oxygen and moisture barrier properties or sensitivity to moisture or oxygen exposure, resistance to degradation to UV light exposure, or other desirable properties but have inadequate mechanical properties that preclude their use as monolithic, unreinforced substrates. The ability to incorporate these solves major environmental stability, service life, and durability/reliability limitations present in existing substrates for flexible electronic applications.

Thin substrate form factors improve the flexibility of devices and enable tighter bend radius for optimum flexibility, bendability and roll ability while maintaining operationally reliable flexible electronic elements. Bending strain on the circuit, device, or element is proportional to the distance that circuit, device, or element is from the neutral axis and the thinner the flexible substrate, the smaller the distances from the neutral axis which reduces In various embodiments, the composite material in accordance to the present disclosure has an overall thinness, and is amendable to locations of circuits, devices, or other elements near the neutral axis so that strains and deformation due to curvature, distortion, bending, or crinkling are minimized Thus, the service life of the circuit, device, or element on the composite material of the present disclosure is, in various embodiments, increased. The above arrangement can enable incorporation of high-resolution electronic devices, elements, circuits, antennas, RF devices, and LEDs into/onto the composite materials herein disclosed.

The structural features of the composite materials of the present disclosure stabilize the features of a circuit so there is minimal fatigue and disbanding of elements in the circuit due to repeated thermal cycles and load/vibration cycles. Uncontrolled CTE mismatch between many electronic elements causes large interfacial stress between the element and the substrate, which causes damage and fracturing of the element from the substrate leading to device failure.

Composite materials in accordance with the present disclosure can be made from thin homogeneous, uniform unitapes that can produce smooth uniform laminates that are also thin, smooth and uniform in properties and thickness. The above arrangement is due to the uniform distribution of the monofilaments within the individual unitape layers. The unitapes can be oriented with ply angles such that the laminates can either have uniform properties in all directions, or the properties can be tailored to match a device, circuit, or other requirements.

The ability to produce a homogeneous, low stretch, low CTE composite material with unidirectional layer orientation and a flat, smooth surface, allows for precise fabrication, deposition, printing, laser ablation, micromachining, etching, doping, vapor deposition, coating, 3D printing, application of multiple thin layers of various electronic materials and a wide range of other common processes that either require a flat or uniform material.

Applications of composite materials of the present disclosure include, but are not limited to: Clothing with integrated antennas and sensors; Conformal applications for radars and antennas; EMI, RF and static protection; Structural membranes with integrated solar cells, wire traces embedded in the laminate, and on-board planar energy storage; Low cost integrated RFID system for package tracking; Flexible circuit boards; Ruggedize flexible displays; and Flexible lighting, amongst other applications.

In various embodiments, conductive or non-conductive additives may be included in the adhesive/resin of the unitape layers to alter the Electrostatic Discharge (ESD) or dielectric (DE) properties of the composite material. In various embodiments, fire retardant adhesives or polymers may be used, or fire retardants can be added to an otherwise flammable matrix or membrane to improve flame resistance.

Flame retarding or self-extinguishing matrix resins, or laminating or bonding adhesives such as Lubrizol 88111, can be used either by themselves or in combination with fire retardant additives. Examples of retardant additives include: DOW D.E.R. 593 Brominated Resin, DOW Corning 3 Fire Retardant Resin, and polyurethane resin with Antimony Trioxide (such as EMC-85/10A from PDM Neptec ltd.), although other fire retardant additives may also be suitable. Fire retardant additives that may he used to improve flame resistance include Fyrol FR-2, Fyrol HF-4, Fyrol PNX, Fyrol 6, and SaFRon 7700, although other additives may also be suitable. Fire retarding or self-extinguishing features can also be added to the fibers within unitape layers either by using fire retardant fibers such as Nomex or Kevlar, ceramic or metallic wire filaments, direct addition of fire retardant compounds to the fiber formulation during the fiber manufacturing process, or by coating the fibers with a sizing, polymer or adhesive incorporating fire retardant compounds listed above or others as appropriate. Any woven or scrim materials used in the laminate may be either be pretreated for fire retardancy by the supplier or coated and infused with fire retardant compounds during the manufacturing process.

In various embodiments, other features that may be imparted to, or incorporated within, the composite materials of the present disclosure include, but are not limited to: Conductive polymer films; Ability to integrate thin flexible glass; Nano-coating of the fibers; Integration of nano-materials into the film and matrix; Integration of EMI, RF, and static protection; Packaging to produce integration of the electronic device's functionality directly into the package; Layered construction analogous to many electrical circuit concepts so they are easily and efficiently integrated into the flexible format; Electrical Resistance; Thermal conductivity for thermal management and heat dissipation; Fiber optics; and Energy storage using multilayered structures.

In alternate embodiments, filaments may be coated prior to processing into unitapes to add functionality such as thermal conductance, electrical capacitance, and the like.

In various other embodiments, metal and dielectric layers may be included within the composite to add functionality such as reflection for solar cells, or capacitance for energy storage.

It will be apparent to those skilled in the art that various modifications and variations can be made in the present disclosure without departing from the spirit or scope of the disclosure. Thus, it is intended that the present disclosure cover the modifications and variations of this disclosure provided they come within the scope of the appended claims and their equivalents.

Likewise, numerous characteristics and advantages have been set forth in the preceding description, including various alternatives together with details of the structure and function of the devices and/or methods. The disclosure is intended as illustrative only and as such is not intended to be exhaustive. It will be evident to those skilled in the art that various modifications may be made, especially in matters of structure, materials, elements, components, shape, size and arrangement of parts including combinations within the principles of the disclosure, to the full extent indicated by the broad, general meaning of the terms in which the appended claims are expressed. To the extent that these various modifications do not depart from the spirit and scope of the appended claims, they are intended to be encompassed therein.

What is claimed is:

1. A composite material comprising:
a. at least one conductive layer; and
b. at least one laminate layer comprising at least one reinforcing layer.

2. The composite material of claim 1, wherein said conductive layer is any one of a non-etched metal layer, an etched-metal layer, a metal ground plane layer, a metal power plane layer, or an electronic circuitry layer.

3. The composite material of claim 2, wherein said conductive layer is an etched-metal layer, said etched-metal tracing a circuit design.

4. The composite material of claim 1, further comprising at least one film layer.

5. The composite material of claim 4, wherein said at least one reinforcing layer is sandwiched between two of said film layers.

6. The composite material of claim 1, wherein said reinforcing layer comprises at least one unidirectional tape sub-layer.

7. The composite material of claim 6, wherein said unidirectional tape sub-layer comprises thinly spread parallel monofilaments coated with a resin.

8. The composite of claim 7, wherein said monofilaments have diameters less than about 60 microns and wherein spacing between individual monofilaments within an adjoining strengthening group of monofilaments is within a gap distance in the range between abutting and/or stacked monofilaments up to about 300 times the monofilament major diameter.

9. The composite material of claim 7, wherein said at least one unidirectional tape sub-layer number four in total, arranged in substantially 0°/+45°/+90°/+135° relative orientation of their monofilaments.

10. The composite material of claim 1, wherein said composite material is a flexible, multilayered circuit board.

11. A flexible electronic composite system comprising at least one composite material of claim 1 incorporated in or on a consumer, industrial, institutional or governmental product.

12. A flexible electronic composite system comprising:
at least one composite material of claim 1; and
hardware and/or software.

13. A method of manufacturing a flexible electronic composite material comprising:
producing a multilayered composite by adding at least one reinforcing layer onto a conductive layer;
optionally etching said conductive layer;
optionally adding additional conductive and/or non-conductive layers into and/or onto said multilayered composite; and
optionally curing said multilayered composite.
